(19) United States
(12) Patent Application Publication
(10) Pub. No.: US 2026/0163020 A1
(43) Pub. Date: Jun. 11, 2026

(54) PRE-COATING OF METAL BIPOLAR PLATE, METHOD OF FORMING THE SAME, METAL BIPOLAR PLATE PRODUCED BY USING THE SAME AND METHOD OF PRODUCING THE SAME

(71) Applicant: METAL INDUSTRIES RESEARCH & DEVELOPMENT CENTRE, KAOHSIUNG (TW)

(72) Inventors: Hsiang Chun HSUEH, Kaohsiung City (TW); Kung-Ming HSU, Kaohsiung City (TW); Tang-Wei LIANG, Kaohsiung City (TW); Jian Wei ZENG, Tainan City (TW)

(21) Appl. No.: 18/976,370

(22) Filed: Dec. 11, 2024

(51) Int. Cl. H01M 8/0228; B21D 26/021; C23C 14/06; C23C 14/35; H01M 8/0206; H01M 8/0213; H01M 8/0215; H01M 8/0258

(52) U.S. Cl. CPC H01M 8/0228; B21D 26/021; C23C 14/0605; C23C 14/0635; C23C 14/352; H01M 8/0206; H01M 8/0213; H01M 8/0215; H01M 8/0258

(57) ABSTRACT

A pre-coating of a metal bipolar plate and a method of forming the same are provided. The pre-coating of the metal bipolar plate is used to form on a surface of a metal substrate. The pre-coating of the metal bipolar plate includes an intermediate layer disposed on the metal substrate, in which the intermediate layer includes transition metal carbide; and a surface conductive layer disposed on the intermediate layer, in which the surface conductive layer includes a graphite layer, and a thickness of the surface conductive layer is in a range of 0.2 μm to 1.0 μm. The pre-coating of the metal bipolar plate can have improved corrosion resistance and electrical conductivity, thereby being applied to the metal bipolar plate and the method of producing the same.

### BACKGROUND

### Field of Invention

The present invention relates to a pre-coating of a metal bipolar plate. More particularly, the present invention relates to the pre-coating of the metal bipolar plate, a method of forming the same, a metal bipolar plate produced by using the same and a method of producing the same.

### Description of Related Art

A bipolar plate is a crucial component within a fuel cell. The bipolar plate should have plenty of gas flow channels and/or cooling channels. The gas flow channels are configured to deliver reaction gas to active catalyst regularly, while the unreacted gas and products are removed via the gas flow channels. The cooling channels are used to distribute coolant in active reaction zone evenly, thereby adsorbing residual heat generated after the fuel cell power generation. Typically, the bipolar plate provides conduction paths for electrons and heat of the fuel cell; thus, the bipolar plate has to have great electricity conductivity and thermal conductivity.

Conventional bipolar plate is often formed by using graphite material, but graphite has low mechanical strength and heavy weight. On the contrary, the metal bipolar plate has greater mechanical strength, and can be produced thinner, thereby decreasing volume and weight of the fuel cell and increasing power density. However, conventional pre-coating of the metal bipolar plate has multilayer structure with a layer number greater than 3 and is doped with noble metal, thereby having properties of corrosion resistance, low impedance, processability, and etc.

Therefore, there is a need to provide a pre-coating of a metal bipolar plate to have both corrosion resistance and processability, while structural complexity and material cost can also be decreased.

### SUMMARY

An aspect of the present invention provides a pre-coating of a metal bipolar plate, which includes an intermediate layer and a surface conductive layer with specific material, thereby having greater corrosion resistance and electrical conductivity.

Another aspect of the present invention provides a method of forming a pre-coating of a metal bipolar plate, which forms the above pre-coating of the metal bipolar plate by using a magnetron sputtering process.

Yet another aspect of the present invention provides a method of producing a metal bipolar plate, which produces the metal bipolar plate by performing a hydroforming operation on the pre-coating of the metal bipolar plate of the above aspect.

Yet another aspect of the present invention provides a metal bipolar plate, which is produced by using the method of the above aspect.

According to the aspect of the present invention, providing the pre-coating of the metal bipolar plate, which is used to be formed on a surface of a metal substrate. The pre-coating of the metal bipolar plate includes an intermediate layer disposed on the metal substrate, in which the intermediate layer is transition metal carbide; and a surface conductive layer disposed on the intermediate layer, in which the surface conductive layer is a graphite layer, and a thickness of the surface conductive layer is in a range from 0.2 μm to 1.0 μm. Based on carbon atom number of the graphite layer as 100%, the graphite layer includes not less than 85% carbon atom with sp2 hybridization.

According to an embodiment of the present invention, a thickness of the intermediate layer is in a range from 0.2 μm to 0.5 μm.

According to an embodiment of the present invention, the transition metal carbide includes chromium carbide or titanium carbide.

According to an embodiment of the present invention, the pre-coating of the metal bipolar plate excludes noble metal.

According to an embodiment of the present invention, a thickness of the metal substrate is in a range from 0.07 mm to 0.15 mm.

According to the another aspect of the present invention, a method of forming a pre-coating of a metal bipolar plate is provided. The method includes forming the above pre-coating of the metal bipolar plate on the surface of the metal substrate by using a magnetron sputtering process.

According to an embodiment of the present invention, the magnetron sputtering process includes performing a first magnetron sputtering operation with a transition metal target and a first carbon target to deposit the intermediate layer on the metal substrate; and performing a second magnetron sputtering operation with a second carbon target to deposit the surface conductive layer on the intermediate layer.

According to an embodiment of the present invention, pressure of the first magnetron sputtering operation and the second magnetron sputtering operation is in a range between 1.3×10⁻³ torr and 1.7×10⁻³ torr.

According to an embodiment of the present invention, the first magnetron sputtering operation is performed for 10 minutes to 20 minutes, and the second magnetron sputtering operation is performed for 60 minutes to 120 minutes.

According to the yet another aspect of the present invention, a method of producing a metal bipolar plate is provided. The method includes performing a hydroforming operation on the above pre-coating of the metal bipolar plate by using a hydraulic mold to form the metal bipolar plate, in which the metal bipolar plate includes plural flow channels.

According to an embodiment of the present invention, a mold core is disposed in the hydraulic mold. The mold core includes an alloy body, in which the alloy body includes plural recesses, and the recesses are configured to form the flow channels of the metal bipolar plate; an intermediate layer conformally disposed on the alloy body, in which the intermediate layer includes transition metal carbide; and a surface film conformally disposed on the intermediate layer, in which the surface film includes a graphite layer, a DLC (diamond like carbon) layer or molybdenum disulfide (MoS₂) layer, and a thickness of the surface film is in a range from 0.5 μm to 2.0 μm.

According to an embodiment of the present invention, when the surface film is the graphite layer, the graphite layer includes not less than 85% carbon atom with sp2 hybridization based on carbon atom number of the graphite layer as 100%.

According to an embodiment of the present invention, when the surface film is the DLC layer, the DLC layer includes not less than 60% carbon atom with sp3 hybridization based on carbon atom number of the DLC layer as 100%.

According to an embodiment of the present invention, the thickness of the surface film is in a range from 0.5 μm to 1.0 μm.

According to an embodiment of the present invention, when the surface film is the molybdenum disulfide layer, the thickness of the surface film is in a range from 0.3 μm to 0.6 μm.

According to an embodiment of the present invention, a hydraulic pressure of the hydroforming operation is in a range from 1000 bar to 1500 bar.

According to the yet another aspect of the present invention, a metal bipolar plate is provided, which is produced by the above method.

Application of the pre-coating of the metal bipolar plate and the method of forming the same, which disposes the intermediate layer and the surface conductive layer including specific material on the metal substrate, thereby increasing corrosion resistance and electrical conductivity. The metal bipolar plate and the method of producing the same by the aforementioned pre-coating of the metal bipolar plate can have better processability and design flexibility.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross section view of a pre-coating of a metal bipolar plate according to some embodiments of the present invention.

FIG. 2 illustrates a cross section view of a coated mold core according to some embodiments of the present invention.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range.

As described above, a pre-coating of a metal bipolar plate, a method of forming the same, a metal bipolar plate produced by using the pre-coating of a metal bipolar plate and a method of producing the same are provided. The pre-coating of a metal bipolar plate is formed by disposing the intermediate layer and the surface conductive layer including specific material on the metal substrate, thereby increasing corrosion resistance and electrical conductivity. Moreover, the metal bipolar plate produced from the pre-coating of the metal bipolar plate by hydroforming can have better processability and design flexibility.

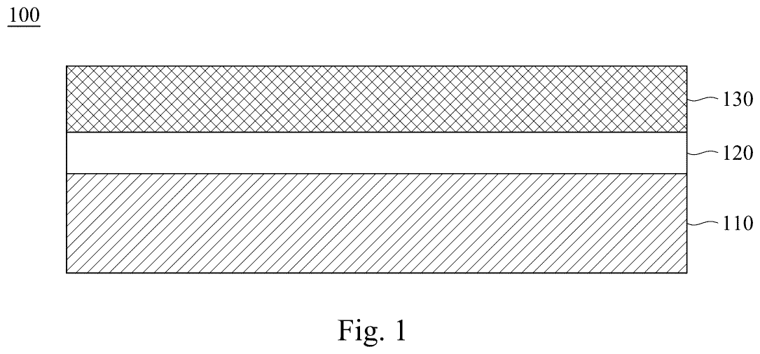

Referring to FIG. 1, FIG. 1 illustrates a cross section view of a pre-coating of a metal bipolar plate 100 according to some embodiments of the present invention. The metal bipolar plate 100 includes a metal plate 110, an intermediate layer 120 and a surface conductive layer 130, in which the intermediate layer 120 is located between the metal substrate 110 and the surface conductive layer 130. In some embodiments, the metal substrate includes stainless steel (for example, 316 stainless steel) or other suitable metal material. In some embodiments, a thickness of the metal substrate 110 is in a range from about 0.07 mm to about 0.15 mm.

The intermediate layer 120 is disposed on the metal substrate 110. In some embodiments, the intermediate layer 120 includes transition metal carbide. In some examples, the transition metal carbide includes chromium carbide (CrC) or titanium carbide. The intermediate layer 120 including the transition metal carbide can increase adhesion force between the intermediate layer 120 and the metal substrate 110 and improve corrosion resistance. In some embodiments, a thickness of the intermediate layer 120 is in a range from about 0.2 μm to about 1.0 μm. If the intermediate layer 120 has the thickness in the aforementioned range, the intermediate layer 120 can have better adhesion and less residual stress.

The surface conductive layer 130 is disposed on the intermediate layer 120. In some embodiments, the surface conductive layer 130 includes a graphite layer. Since the graphite layer has remarkable electrical conductivity and self-lubricating property, it is suitable to use as surface conductive material for the pre-coating of the metal bipolar plate 100. In the aforementioned embodiments, based on carbon atom number of the graphite layer as 100%, the graphite layer includes not less than 85% carbon atom with sp2 hybridization, while the remaining is amorphous carbon with sp3 hybridization. The graphite layer is preferable to have the aforementioned ratio of carbon atom with sp2 hybridization, thereby having better electrical conductivity and surface lubricity; moreover, effect such as providing lubricity and reducing friction can be achieved during following process of forming the metal bipolar plate, thereby avoiding the plate from breaking under high strain.

In some embodiments, a thickness of the surface conductive layer 130 is in a range from about 0.2 μm to about 1.0 μm. If the thickness of the surface conductive layer 130 is too less (such as less than 0.2 μm), the processability of producing the metal bipolar plate is not fine, that is, it is susceptible to breakage or damage during the molding process. In other words, when the surface conductive layer 130 has the specific thickness, the design flexibility of the metal bipolar plate can be increased.

Compared to the conventional pre-coating of the metal bipolar plate, in some embodiments, the intermediate layer 120 and the surface conductive layer 130 of the pre-coating of the metal bipolar plate 100 both exclude noble metal. Compared to the conventional pre-coating of the metal bipolar plate having a multi-layer structure with more than three layers, in some embodiments, the pre-coating of the metal bipolar plate 100 only consists of the metal substrate 110, the intermediate layer 120 and the surface conductive layer 130. Therefore, the pre-coating of the metal bipolar plate 100 of the present invention can reduce process cost and material cost of the multi-layer structure.

The method of forming the above pre-coating of the metal bipolar plate 100 uses a magnetron sputtering process to form the pre-coating of the metal bipolar plate on the surface of the metal substrate. Specifically, the method includes providing the metal substrate 110, and depositing the intermediate layer 120 and the surface conductive layer 130 in order by the magnetron sputtering process. In some embodiments, before the magnetron sputtering process, a pre-treatment step is performed on the metal substrate 110. In some examples, the pre-treatment step includes performing pre-treatment by using argon and oxygen in order under vacuum environment with pressure of about 2.5×10⁻³ torr to about 5.0×10⁻³ torr for about 15 minutes to about 30 minutes, in which flow rate of argon and oxygen can be about 130 sccm (standard cubic centimeter per minute) to about 260 sccm.

In some embodiments, the magnetron sputtering process includes performing a first magnetron sputtering operation first by using a transition metal target and a carbon target, thereby depositing the intermediate layer 120 including the transition metal carbide on the metal substrate 110. In some examples, when the intermediate layer 120 includes chromium carbide, one chromium target and two carbon targets can be used, in which electrical current for the chromium target can be set as about 1 A to about 2.5 A, while electrical current for the carbon targets can be set as about 0.2 A to about 1 A. In such example, pressure of the first magnetron sputtering operation is in a range between about 1.3×10⁻³ torr and about 1.7×10⁻³ torr, argon is introduced with a flow rate of about 30 sccm to about 60 sccm, and the magnetron sputtering operation is performed for about 10 minutes to about 20 minutes. Chromium carbide can be deposited with better compactness by using the aforementioned condition.

In some embodiments, a second magnetron sputtering operation can be performed by using carbon targets, thereby depositing the surface conductive layer 130 on the intermediate layer 120. In some examples, two carbon targets can be used, in which electrical current of the carbon targets can be set as about 0.2 A to about 1 A. In such example, pressure of the second magnetron sputtering operation is in a range between about 1.3×10⁻³ torr and about 1.7×10⁻³ torr, argon is introduced with the flow rate of about 30 sccm to about 60 sccm, and the magnetron sputtering operation is performed for about 60 minutes to about 120 minutes. The graphite layer can be deposited with better compactness and greater ratio of carbon atom with sp2 hybridization by using the aforementioned condition.

The present invention further provides a method of producing the metal bipolar plate, which includes performing a hydroforming operation on the above pre-coating of the metal bipolar plate (such as the pre-coating of the metal bipolar plate 100) by using a hydraulic mold, thereby producing the metal bipolar plate with plural flow channels. Flow channel widths, rib widths, ratio of the flow channel width to the rib width and a depth of the metal bipolar plate can be decided according to application requirements, and the present invention is not limited thereto. In some embodiments, the ratio of the flow channel width to the rib width of the metal bipolar plate is about 1.0 to about 1.5. In some embodiments, a hydraulic pressure of the hydroforming operation is in a range from 1000 bar to 1500 bar.

In some embodiments, a mold core is disposed in the above hydraulic mold, and the mold core can have specific coating to have better lubricity, and further assure that the metal bipolar plate can be demolded during the hydroforming process. It is understood that the mold core should include plural recesses according to the flow channels of the desired metal bipolar plate.

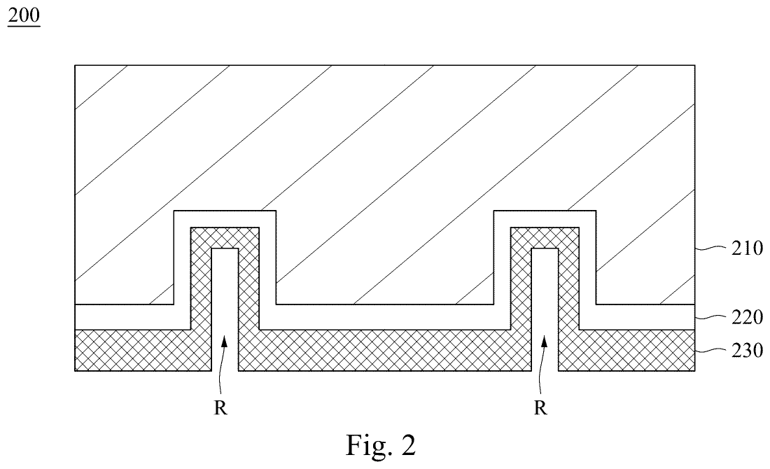

Referring to FIG. 2, FIG. 2 illustrates a cross section view of a coated mold core 200 according to some embodiments of the present invention. The coated mold core 200 includes an alloy body 210, an intermediate layer 220 and a surface film 230. The alloy body 210 includes a number of recesses R, which are configured to form the flow channels of the metal bipolar plate. In some embodiments, material of the alloy body 210 includes alloy steel or other suitable alloy material.

The intermediate layer 220 is conformally disposed on a surface of the alloy body 210. In some embodiments, the intermediate layer includes transition metal carbide. In some examples, the transition metal carbide includes chromium carbide (CrC) or titanium carbide. In such embodiment, a thickness of the intermediate layer 220 is about 0.1 μm. The intermediate layer 220 includes the transition metal carbide and/or has specific thickness can increase adhesion force between the intermediate layer 220 and the surface film 230 and the surface of the alloy body 210.

The surface film 230 is conformally disposed on the intermediate layer 220. In some embodiments, the surface film 230 can be a graphite layer, a DLC (diamond like carbon) layer or molybdenum disulfide (MoS₂) layer, and can match with the surface conductive material of the metal bipolar plate desired to be form, thereby providing better lubricity and wear resistance, and it can be understood by those skilled in the art.

In some embodiments that the surface film 230 is the graphite layer, the graphite layer includes not less than 85% carbon atom with sp2 hybridization based on carbon atom number of the graphite layer as 100%. In the aforementioned embodiments, a thickness of the surface film 230 is in a range from about 0.5 μm to about 2.0 μm. When the surface film 230 is the graphite layer, and has the aforementioned properties, the better lubricity and the better demolded property can be provided to the metal bipolar plate, and friction between the hydraulic mold and the metal bipolar plate can be reduced, thereby avoiding the metal bipolar plate from breaking. Thus, the coated mold core 200 including the graphite layer is suitable for manufacturing the metal bipolar plate with higher aspect ratio.

In some embodiments that the surface film 230 is the DLC layer, the DLC layer includes not less than 60% carbon atom with sp3 hybridization based on carbon atom number of the DLC layer as 100%. In the aforementioned embodiments, the thickness of the surface film 230 is in a range from about 0.5 μm to about 1.0 μm. When the surface film 230 is the DLC layer, and has the aforementioned properties, the coated mold core 200 can have greater hardness and wear resistance. Thus, the coated mold core 200 including the DLC layer is suitable for manufacturing the metal bipolar plate with smaller aspect ratio.

In some embodiments that the surface film 230 is the molybdenum disulfide layer, the thickness of the surface film 230 is in a range from about 0.3 μm to about 0.6 μm. When the surface film includes the molybdenum disulfide layer, and has the aforementioned thickness, better lubricity can be provided.

The metal bipolar plate produced by the above method can have better corrosion resistance and electrical conductivity.

The following Embodiments are provided to better elucidate the practice of the present invention and should not be interpreted in anyway as to limit the scope of same. Those skilled in the art will recognize that various modifications may be made while not departing from the spirit and scope of the invention. All publication and patent applications mentioned in the specification are indicative of the level of those skilled in the art to which this invention pertains.

### Embodiment 1

The pre-coating of the metal bipolar plate is formed by Embodiment 1. First, the 316L stainless steel metal substrate with the thickness of 0.1 mm was rinsed, which includes ultrasonic cleaner for 30 minutes by using ethanol and acetone, and then dried for 90 minutes in an oven. Additionally, a chamber of physical vapor deposition (PVD) was vacuumized to the pressure of 5×10⁻⁶ torr.

Subsequently, the pre-treatment step was performed on the stainless steel metal substrate, which includes introducing argon and oxygen for 30 minutes with the flow rate of 130 sccm under the pressure of 5×10⁻³ torr. Then, one chromium target and two carbon targets were used to perform the first magnetron sputtering operation, thereby depositing the intermediate layer including chromium carbide on the stainless steel metal substrate. The electrical current for the chromium target was set as 1 A, while the electrical current for the carbon target was set as 0.2 A. The pressure of the first magnetron sputtering operation was 1.5×10⁻³ torr. The argon was introduced with the flow rate of 60 sccm, and the magnetron sputtering operation was performed for 10 minutes. Thus, the intermediate layer of chromium carbide with the thickness of 0.1 μm was formed.

Then, the two carbon targets were used to perform the second magnetron sputtering operation, thereby depositing the surface conductive layer on the intermediate layer. The electrical current for the carbon target was set as 0.2 A. The pressure of the second magnetron sputtering operation was 1.5×10⁻³ torr. The argon was introduced with the flow rate of 60 sccm, and the magnetron sputtering operation was performed for 120 minutes. Thus, the graphite layer with the thickness of 0.774 μm was formed. Then, the pre-coating of the metal bipolar plate was obtained after cooling in the air for 3 hours.

Raman spectroscopy was used to examine content of graphite (i.e. carbon atom with sp2 hybridization) of the surface conductive layer within the pre-coating of the metal bipolar plate of Embodiment 1. The result obtained was that intensity ratio of D peak to G peak (Id/Ig) of 2.02, which meant that the graphite content (i.e. carbon atom with sp2 hybridization) of the surface conductive layer was 85%.

In addition, electrochemical detection method was used to examine the corrosion current of the pre-coating of the metal bipolar plate of Embodiment 1. The results obtained was that anode current was 0.98 μA/cm², the cathode current was 0.64 μA/cm², and contact resistance was 8.98 mΩ-cm². The corrosion resistance standard for bipolar plate required by department of energy (DOE) was that the anode current and the cathode current were both less than 1 μA/cm², and the contact resistance was less than 0.01 Ω-cm² (i.e. 10 mΩ-cm²). Thus, the pre-coating of the metal bipolar plate of Embodiment 1 indeed complied with the corrosion resistance standard required by DOE.

### Embodiment 2 and Comparative Example 2

The hydroforming operation (with the hydraulic pressure of 1500 bar) was performed on the pre-coating of the metal bipolar plate of Embodiment 1 and the 316L stainless steel metal substrate with the thickness of 0.1 mm, respectively, thereby producing the metal bipolar plate of Embodiment 2 and Comparative example 1. Embodiment 2 and Comparative example 1 produced a group of the metal bipolar plate with the flow channel width to the rib width of 1.48 (the flow channel width was 1.61 mm, and the rib width was 1.09 mm), and the flow channel depth of 0.5 mm, 0.42 mm and 0.34 mm; and a group of the metal bipolar plate with the flow channel width to the rib width of 1.1 (the flow channel width was 0.9 mm, and the rib width was 0.8 mm), and the flow channel depth of 0.5 mm, 0.42 mm and 0.34 mm. The obtained result was that the metal bipolar plate of Comparative example 1 with the flow channel width to the rib width of 1.1 and the flow channel depth of 0.5 mm and 0.42 mm were broken, while the metal bipolar plate of Embodiment 2 were all complete without breaking. Thus, it indeed showed better processability and design flexibility.

According to above embodiments, the pre-coating of a metal bipolar plate, the method of forming the same, the metal bipolar plate produced by using the pre-coating of the metal bipolar plate and the method of producing the same are provided. The pre-coating of a metal bipolar plate is formed by disposing the intermediate layer and the surface conductive layer including specific material on the metal substrate, thereby increasing corrosion resistance and electrical conductivity. Moreover, the metal bipolar plate produced from the pre-coating of the metal bipolar plate by hydroforming can have better processability and design flexibility.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A pre-coating of a metal bipolar plate, used to be formed on a surface of a metal substrate, comprising:
an intermediate layer, disposed on the metal substrate, wherein the intermediate layer is transition metal carbide; and
a surface conductive layer, disposed on the intermediate layer, wherein the surface conductive layer is a graphite layer, and a thickness of the surface conductive layer is in a range from 0.2 μm to 1.0 μm,
wherein based on carbon atom number of the graphite layer as 100%, the graphite layer comprises not less than 85% carbon atom with sp2 hybridization.

2. The pre-coating of the metal bipolar plate of claim 1, wherein a thickness of the intermediate layer is in a range from 0.2 μm to 0.5 μm.

3. The pre-coating of the metal bipolar plate of claim 1, wherein the transition metal carbide comprises chromium carbide or titanium carbide.

4. The pre-coating of the metal bipolar plate of claim 1, wherein the pre-coating of a metal bipolar plate excludes noble metal.

5. The pre-coating of the metal bipolar plate of claim 1, wherein a thickness of the metal substrate is in a range from 0.07 mm to 0.15 mm.

6. A method of forming a pre-coating of a metal bipolar plate, which forms the pre-coating of a metal bipolar plate of claim 1 on the surface of the metal substrate by using a magnetron sputtering process.

7. The method of forming a pre-coating of a metal bipolar plate of claim 6, wherein the magnetron sputtering process comprises:
performing a first magnetron sputtering operation with a transition metal target and a first carbon target to deposit the intermediate layer on the metal substrate; and
performing a second magnetron sputtering operation with a second carbon target to deposit the surface conductive layer on the intermediate layer.

8. The method of claim 7, wherein pressure of the first magnetron sputtering operation and the second magnetron sputtering operation is in a range between 1.3×10⁻³ torr and 1.7×10⁻³ torr.

9. The method of claim 7, wherein the first magnetron sputtering operation is performed for 10 minutes to 20 minutes, and the second magnetron sputtering operation is performed for 60 minutes to 120 minutes.

10. A method of producing a metal bipolar plate, comprising:
performing a hydroforming operation on the pre-coating of the metal bipolar plate of claim 1 by using a hydraulic mold to form the metal bipolar plate, wherein the metal bipolar plate comprises a plurality of flow channels.

11. The method of claim 10, wherein a mold core is disposed in the hydraulic mold, the mold core comprises:
an alloy body, wherein the alloy body comprises a plurality of recesses, and the recesses are configured to form the flow channels of the metal bipolar plate;
an intermediate layer, conformally disposed on the alloy body, wherein the intermediate layer includes transition metal carbide; and
a surface film, conformally disposed on the intermediate layer, wherein the surface film includes a graphite layer, a DLC (diamond like carbon) layer or molybdenum disulfide (MoS₂) layer, and a thickness of the surface film is in a range from 0.5 μm to 2.0 μm.

12. The method of claim 11, wherein when the surface film is the graphite layer, the graphite layer comprises not less than 85% carbon atom with sp2 hybridization based on carbon atom number of the graphite layer as 100%.

13. The method of claim 11, wherein when the surface film is the DLC layer, the DLC layer comprises not less than 60% carbon atom with sp3 hybridization based on carbon atom number of the DLC layer as 100%.

14. The method of claim 13, wherein the thickness of the surface film is in a range from 0.5 μm to 1.0 μm.

15. The method of claim 11, wherein when the surface film is the molybdenum disulfide layer, the thickness of the surface film is in a range from 0.3 μm to 0.6 μm.

16. The method of claim 10, wherein a hydraulic pressure of the hydroforming operation is in a range from 1000 bar to 1500 bar.

17. A metal bipolar plate, which is produced by the method of claim 11.
